(19) United States
(12) Patent Application Publication
(10) Pub. No.: US 2010/0243041 A1
(43) Pub. Date: Sep. 30, 2010

(54) Apparatus and Method for Solar Cells with Laser Fired Contacts in Thermally Diffused Doped Regions

(75) Inventors: David E. Carlson, Williamsburg, VA (US); Lian Zou, Point of Rocks, MD (US); Murray S. Bennett, Frederick, MD (US); George Hmung, Gaithersburg, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 12/726,600

(22) Filed: Mar. 18, 2010

Related U.S. Application Data
(60) Provisional application No. 61/163,687, filed on Mar. 26, 2009.

(51) Int. Cl. H01L 31/00; H01L 31/18; H01L 31/0248; H01L 31/0232

(52) U.S. Cl. 136/255; 438/69; 438/87; 438/98; 257/E31.002; 257/E31.127; 257/E31.111

(57) ABSTRACT

This invention relates to an apparatus and a method for solar cells with laser fired contacts in thermally diffused doped regions. The cell includes a doped wafer and a plurality of first highly doped regions having a first conductivity type. The cell also includes a plurality of second highly doped regions having an opposite conductivity type from the first conductivity type and a passivation layer disposed over at least a portion of each the plurality of first highly doped regions and the plurality of second highly doped regions. The cell also includes a network of conductors having a first conductor and a second conductor, and a plurality of contacts electrically connecting the first highly doped regions with the first conductor and electrically connecting the second highly doped regions with the second conductor.

This application claims the benefit of U.S. Provisional Patent Application No. 61/163,687 filed Mar. 26, 2009, which is incorporated herein by reference in its entirety.

### BACKGROUND

1. Technical Field

This invention relates to an apparatus and a method for solar cells with laser fired contacts in thermally diffused doped regions.

2. Discussion of Related Art

Photovoltaic cells convert incident light into electrical energy. Known photovoltaic cells use many costly and time consuming manufacturing steps including several high temperature processes.

Carlson, U.S. Patent Application Publication 2006/0130891 (Carlson '891) discloses back-contact photovoltaic cells. Carlson '891 discloses a photovoltaic cell including a wafer made from a semiconductor material of a first conductivity type. The wafer includes a first, light receiving surface, a second surface opposite the first surface on the wafer, and a diffusion length. The photovoltaic cell includes a first passivation layer positioned over the first surface of the wafer, a first electrical contact positioned over the second surface of the wafer, and a second electrical contact positioned over the second surface of the wafer and separated electrically from the first electrical contact. The photovoltaic cell includes a second passivation layer positioned over the second surface of the wafer in the region that is at least between the first electrical contact and the second surface of the wafer. The photovoltaic cell includes a layer made from a semiconductor material of a conductivity opposite the conductivity of the wafer and positioned in the region between the second passivation layer and the first electrical contact. The entire teachings of U.S. Patent Application Publication 2006/0130891 are hereby incorporated by reference in its entirety.

Carlson, U.S. Patent Application Publication 2007/0137692 (Carlson '692) discloses back-contact photovoltaic cells. Carlson '692 discloses a photovoltaic cell including a wafer made from a semiconductor material of a first conductivity type, a first light receiving surface and a second surface opposite the first surface. The photovoltaic cell includes a first passivation layer positioned over the first surface of the wafer, and a first electrical contact comprising point contacts positioned over the second surface of the wafer and having a conductivity opposite to that of the wafer. The photovoltaic cell includes a second electrical contact comprising point contacts positioned over the second surface of the wafer and separated electrically from the first electrical contact and having a conductivity the same as that of the wafer. The entire teachings of U.S. Patent Application Publication 2007/0137692 are hereby incorporated by reference in its entirety.

Carlson et al., International Patent Application Publication WO 2008/115814 discloses solar cells. Carlson et al. discloses a photovoltaic cell including a semiconductor wafer with a front, light receiving surface and an opposite back surface. The photovoltaic cell includes a passivation layer on at least the back surface, a doped layer opposite in conductivity type to the wafer over the passivation layer, an induced inversion layer, and a dielectric layer over the doped layer. The photovoltaic cell includes one or more localized emitter contacts and one or more localized base contacts on at least the back surface extending at least through the dielectric layer. Preferably, the localized emitter contact or contacts and localized base contact or contacts are all on the back surface of the photovoltaic cell. The localized emitter contact and localized base contacts are suitably laser fired contacts.

Carlson et al. also discloses a neutral surface photovoltaic cell including a semiconductor wafer with a front, light receiving surface and an opposite back surface, a neutral passivation layer on at least the back surface, a dielectric layer over the passivation layer, and one or more localized emitter contacts and one or more localized base contacts on at least the back surface extending at least through the dielectric layer. Preferably, the localized emitter contacts and localized base contact or contacts are all on the back surface of the photovoltaic cell. The localized emitter contacts and localized base contacts are suitably laser fired contacts. Neutral surface refers to where the cell does not have a purposely induced inversion layer or accumulation layer and, preferably, does not have an inversion layer or an accumulation layer. The entire teachings of International Patent Application Publication WO 2008/115814 are hereby incorporated by reference in its entirety.

There is a need and a desire for photovoltaic cells made using fewer manufacturing steps than conventional photovoltaic cells. There is also a need and a desire for photovoltaic cells made using fewer high temperature processes. There is also a need and a desire for photovoltaic cells with high quality laser fired contacts. There is also a need and a desire for photovoltaic cells made more quickly and cost effectively.

### SUMMARY

This invention relates to an apparatus and/or a method for solar cells with laser fired contacts in thermally diffused doped regions. This invention includes photovoltaic cells made using fewer manufacturing steps than conventional photovoltaic cells. This invention also includes photovoltaic cells made using fewer high temperature processes. This invention also includes photovoltaic cells with high quality laser fired contacts. This invention also includes photovoltaic cells made more quickly and/or cost effectively.

According to a first embodiment, this invention includes a back-contact photovoltaic cell. The cell includes a doped wafer of semiconductor material having a front surface and a back surface. The cell also includes a plurality of first highly doped regions disposed with respect to the back surface and having a first conductivity type. The cell also includes a plurality of second highly doped regions disposed with respect to the back surface and having an opposite conductivity type from the first conductivity type. The cell also includes a passivation layer disposed over at least a portion of each of the plurality of first highly doped regions, the plurality of second highly doped regions, and/or the remaining back surface. The cell also includes a network of conductors disposed with respect to the passivation layer and having a first conductor and a second conductor. The cell also includes a plurality of contacts electrically connecting the first highly doped regions with the first conductor and electrically connecting the second highly doped regions with the second conductor.

According to a second embodiment, this invention includes a photovoltaic cell. The cell includes a doped wafer of semiconductor material having a front surface and a back surface. The cell also includes a plurality of highly doped regions disposed with respect to the front surface and having a conductivity type opposite the doped wafer. The cell also includes a shallow emitter disposed between the plurality of highly doped regions and having a same conductivity type as the highly doped regions. The cell also includes a back surface field region just beneath the back surface. The back surface field region is formed either by a highly doped region having a same conductivity type as the doped wafer or by an undoped layer of an amorphous silicon alloy and a highly doped layer of a same conductivity type as the doped wafer. The cell also includes a front passivation layer disposed with respect to the highly doped regions and/or the shallow emitter. The cell also includes a back passivation layer disposed with respect to the back surface field region. The cell also includes a current collection grid disposed with respect to the front passivation layer and electrically connected to the highly doped regions. The cell also includes a conductor disposed with respect to the back passivation layer. The cell also includes a plurality of contacts electrically connecting the back surface field region with the conductor.

According to a third embodiment, this invention includes a process of manufacturing back-contact photovoltaic cells. The process includes the step of applying a first dopant source to a portion of a back surface of a doped wafer of semiconductor material. The first dopant source has a first conductivity type. The process also includes the step of applying a second dopant source to a different portion of the back surface of the doped wafer of semiconductor material. The second dopant source has an opposite conductivity type from the first conductivity type. The process also includes the step of diffusing the first dopant source and/or the second dopant source into the doped wafer to form a plurality of first highly doped regions and/or a plurality of second highly doped regions. The process also includes the step of cleaning the back surface. The process also includes the step of laying a passivation layer over the back surface, the plurality of first highly doped regions, and/or the plurality of second highly doped regions. The process also includes the step of applying a network of conductors to a portion of the passivation layer. The process also includes the step of forming contacts between the network of conductors and both the first highly doped regions and the second highly doped regions.

According to a fourth embodiment, this invention includes a process of manufacturing photovoltaic cells. The process includes the step of applying a dopant source to a portion of a front surface of a doped wafer of semiconductor material. The dopant source has a conductivity type opposite the doped wafer. The process also includes the step of applying a dilute dopant source having a conductivity type opposite the doped wafer to the remainder of the front surface of the doped wafer. The process also includes the step of applying a dopant source to a portion of a back surface of a doped wafer and the dopant source having the same conductivity type as the doped wafer. The process also includes the step of diffusing the dopant sources and/or the dilute dopant source into the doped wafer to form highly doped regions, a shallow emitter, and/or a back surface field region. The process also includes the step of laying a passivation layer over the highly doped regions, the shallow emitter, the back surface, and/or the back surface field region to form a front passivation layer and/or a back passivation layer. The process also includes the step of applying a current collection grid on or with respect to the front passivation layer. The process also includes the step of applying a conductor on the back passivation layer. The process also includes the step of forming front-contacts between the highly doped regions and the current collection grid. The process also includes the step of forming back-contacts between the back surface field region and the conductor.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention. In the drawings:

FIG. 1A illustrates a partial side sectional view of a back-contact photovoltaic cell, according to one embodiment;

FIG. 1B illustrates a rear planar view of the back-contact photovoltaic cell of FIG. 1A, according to one embodiment;

FIG. 2 illustrates a partial side sectional view of a back-contact photovoltaic cell with a shallow emitter, according to one embodiment;

FIG. 3 illustrates a partial side sectional view of a back-contact photovoltaic cell with a shallow emitter, according to one embodiment;

FIG. 4A illustrates a partial side sectional view of a back-contact photovoltaic cell with a shallow emitter, according to one embodiment;

FIG. 4B illustrates a rear planar view of the back-contact photovoltaic cell with the shallow emitter of FIG. 4A, according to one embodiment;

FIG. 5 illustrates a partial side sectional view of a back-contact photovoltaic cell with an inversion layer, according to one embodiment;

FIG. 6 illustrates a partial side sectional view of a photovoltaic cell, according to one embodiment;

FIG. 7 illustrates a partial side sectional view of a photovoltaic cell, according to one embodiment;

FIG. 8 illustrates a rear planar view of a network of conductors, according to one embodiment;

FIG. 9 illustrates a partial side sectional view of a photovoltaic cell, according to one embodiment;

FIG. 10 illustrates a front planar view of a wafer with selective emitter regions and current collection fingers, according to one embodiment;

FIG. 11 schematically illustrates an apparatus used for parallel laser firing contacts, according to one embodiment;

FIG. 12A schematically illustrates a one dimensional scan for parallel laser firing contacts, according to one embodiment;

FIG. 12B schematically illustrates a one dimensional stage for parallel laser firing contacts, according to one embodiment;

FIG. 13A schematically illustrates a two dimensional scan for parallel laser firing contacts, according to one embodiment;

FIG. 13B schematically illustrates a two dimensional scan for parallel laser firing contacts according to one embodiment;

FIG. 13C schematically illustrates a two dimensional stage for parallel laser firing contacts, according to one embodiment; and

FIG. 13D schematically illustrates a two dimensional stage for parallel laser firing contacts, according to one embodiment.

### DETAILED DESCRIPTION

This invention relates to an apparatus and a method for solar cells with laser fired contacts in thermally diffused doped regions. This invention may include high quality contacts by laser firing metals or other highly conductive materials in and/or into thermally diffused doped regions in crystalline silicon or other suitable substrates. This invention allows the formation of high quality emitters or localized emitters using laser firing, such as without laser induced defects and/or with minimal laser induced defect that can be formed by laser firing an opposite conductivity type dopant into a lightly doped substrate.

Laser firing of aluminum into an n-type silicon wafer can form an emitter contact but often may result in laser induced damage in the vicinity of the emitter. The laser induced damage can limit the solar cell performance (efficiency), especially in wafers with resistivities in the range of about 1 ohm-centimeter to about 10 ohm-centimeter. However, if an emitter region can be first formed by thermal diffusion and/or other suitable processes, then laser firing into that diffused emitter region can minimize the effect of laser induced damage since the laser fired contact only needs to make an ohmic contact to and/or with the diffuse emitter region. Once minority carriers are collected by a thermally diffused emitter, the minority carriers become majority carriers within the emitter region and may not be strongly affected by laser induced defects in the vicinity of the laser fired contact.

According to one embodiment, dopant inks such as n⁺⁺ and p⁺⁺ materials can be inkjet printed, aerosol jet printed, jet dispensed (micro-dispensed), and/or the like onto localized regions on the rear surface of a wafer, and the dopants can be thermally diffused into the wafer. Dopants with an n⁺ label refer to negative type dopants and dopants with a p⁺ label refer to positive type dopants. Dopants with an n⁺⁺ label refer to heavily doped negative type dopants and dopants with a p⁺⁺ label refer to heavily doped positive type dopants. Generally, electrons are the majority carriers in regions doped with an n⁺ or n⁺⁺ dopant and holes are the majority carriers in regions doped with a p⁺ or p⁺⁺ dopant.

Passivating dielectric layers can be applied to both the front surface and the rear surface. Interdigitated metal fingers can be inkjet printed so that one finger pattern lays over the n⁺⁺ diffused regions and the other finger pattern lays over the p⁺⁺ diffused regions. A laser can be used to laser fire the metal into the localized thermally diffused regions. Various lasers can be used for this application, for example, but not limited to: Nd:YAG lasers at 1064 nanometers, 532 nanometers, 355, nanometers, 266 nanometers; excimer lasers at 351 nanometers, 308 nanometers, 248 nanometers, 193 nanometers; and/or the like. In this embodiment using a p-type wafer, the passivation layers on the rear can include i-n⁺ a-Si:H/SiO_{y} (amorphous silicon and silica which induces an inversion layer). Optionally, an isolation ink can be printed in the region around the p⁺⁺ diffused region to prevent shunting or the occurrence of leakage currents between the p⁺⁺ region and the inversion layer.

According to one embodiment, the photovoltaic cell can use a shallow diffused n⁺ emitter region instead of an induced inversion layer so the i-n⁺ a-Si:H layers does not have to be included.

Embodiments with an n-type wafer may use i-p⁺ a-Si:H/SiO_{y} plasma enhanced chemical vapor deposition layers in conjunction with an isolation ink around the localized base (n⁺⁺) contacts. In the alternative, a shallow diffused p⁺ emitter region in conjunction with an isolation ink around the localized base contacts can be used.

According to one embodiment, high quality localized rear contacts can be formed by laser firing aluminum through a dielectric into a shallow back surface field region. For a p-type wafer, the back surface field region could be formed by coating the rear surface with an ink containing boron, aluminum, indium, gallium, and/or the like. The manufacturing process may include laser firing a top silver current collection grid into thermally diffused n⁺⁺ fingers on the front surface.

This invention involves may include using a laser to form high quality localized contacts by firing (melting and/or diffusing) a metal through a passivating dielectric layer into localized and/or extended doped regions formed by thermal diffusion.

Photovoltaic cells may sometimes be referred to as solar cells and may convert or transform electromagnetic radiation into electrical energy or the flow of electrons, such as in solar panels and/or solar modules. Electromagnetic radiation broadly includes infrared wavelengths, visible light wavelengths, ultraviolet wavelengths and/or the like, such as from the Sun.

According to one embodiment, this invention may include front solar cell contacts in the form of laser fired selective emitters and rear solar cell contacts in the form of laser fired localized back-surface field contacts. The selective emitter may include a shallow emitter, such as a lightly doped emitter with a sheet resistance about 100 ohm per square. The shallow emitter can be formed or made by diffusing a small amount of phosphorus or other suitable dopant into the wafer, such as by using phosphorus oxychloride (POCl₃) at about 850 degrees Celsius, for example.

Residual phosphosilicate glass or other impurities from the surface of a wafer can be removed. A deposit of a silicon nitride coating or other suitable antireflection coating can be made, such as using plasma enhanced chemical vapor deposition and/or the like. Desirably, an inkjet printer, an aerosol jet printer, and/or the like can be used to deposit localized regions of an n⁺ doping ink, such as a silicon ink heavily doped with phosphorus on top of the antireflection coating. An inkjet printer, an aerosol jet printer, and/or the like may also deposit a conductive finger grid and/or a current collection grid, such as both made from silver or other suitable conductive material. A laser may be used to form selective emitter contacts by laser firing the conductive material (silver) into the localized n⁺ doping inks and into the silicon wafer.

According to one embodiment, this invention may include an amorphous silicon heterojunction to induce an emitter layer at the front surface of a solar cell with a p-type wafer. This embodiment may further include a dielectric antireflection coating applied as an overcoat to the heterojunction. The solar cell may also include localized doping inks and conductive electrodes deposited with an inkjet printer, an aerosol jet printer, and/or the like. The solar cell may also include laser fired selective emitter contacts. The structure of the induced emitter may include a thin intrinsic amorphous silicon layer, such as about 10 nanometers in thickness. The structure of the induced emitter may further include a thin doped amorphous silicon layer, such as with phosphorus dopant and about 15 nanometers in thickness. The solar cell may also include a layer of dielectric material, such as silicon nitride with a thickness of about 80 nanometers.

In the alternative, for an n-type wafer, a similar structure can be used but the doped amorphous silicon layer can contain a p-type dopant, such as boron. The solar cell may also include selective emitter contacts formed by laser firing the conductive material through a p⁺ doping ink.

According to one embodiment, an induced emitter can be formed by using a dielectric layer containing a fixed charge. For example, in the case of a p-type wafer, plasma enhanced chemical vapor deposited silicon nitride can contain a fixed positive charge density of about 10¹² per centimeter square. The charge density can induce an emitter near the front surface of the solar cell. Also for example, in the case of a n-type wafer, atomic layer deposited aluminum oxide (Al₂O₃) can contain a negative fixed charge density of about 10¹³ per centimeter square. The charge density can induce an emitter near the front surface of the solar cell. Any suitable charge density is within the scope of this invention.

According to one embodiment, this invention may include a shallow emitter or an induced emitter formed over most of the front surface of a silicon wafer. The front surface can be coated with a dielectric passivation layer. An inkjet printer or an aerosol jet printer can be used to deposit an emitter doping ink over the dielectric. A grid or finger pattern can be formed on top of the dielectric and the doping ink regions. A laser may be used to form selective emitter contacts and/or localized emitter contacts by laser firing a metal into the silicon wafer in those regions containing the emitter doping ink.

Solar cells can be improved by using a shallow emitter, such as for better blue response. Also solar cells can be improved by using selective emitter contacts (lower series resistance) and by using doped silicon fingers to assist in the collection of photogenerated carriers, such as better short circuit current density (Jsc) due to less shading losses.

A selective emitter solar cell can be fabricated by depositing a pattern of doping ink lines on a silicon wafer using an inkjet printer, an aerosol jet printer, and/or the like. A shallow emitter can be formed over most of the front surface of the wafer by doping using phosphoric acid vapor deposition or phosphorus oxychloride, for example. A silicon nitride layer or other suitable antireflection layer can be deposited. The solar cell may include a current collection grid comprising both current collection fingers and busbars directly over the selective emitter regions and fire a conductive material into the silicon wafer, such as silver frit paste or a silver ink. In the alternative, the doping ink lines could also be deposited after forming a shallow emitter and before the silicon nitride deposition. The doping ink lines can be deposited in a pattern that forms two sets of lines, such as at generally right angles (about perpendicular) with respect to each other. The first set of lines can form an n⁺ selective emitter contact for a p-type emitter that will lie directly under the conductive (silver) fingers and/or busbars. The second set of lines can form thin heavily doped n⁺ silicon lines that assist in the collection of photocurrent. The doping ink lines may form a network, a grid, a matrix, a web, and/or the like.

The doping ink lines can be deposited using noncontact printing, inkjet printing, aerosol jet printing, and/or the like. The dopants can be diffused into the silicon wafer using thermal processing, rapid thermal processing (RTP), and/or the like. Rapid thermal processing may be used before forming the shallow emitter so as to assure heavily doped selective emitter regions and heavily doped current collection fingers.

According to one embodiment, the invention may include depositing the doping ink for the selective emitter in localized regions while the doping ink for the current collection fingers can be deposited in continuous lines. After depositing an antireflection coating, a conductive frit can be deposited or applied that can fire through the antireflection coating in those regions overlying the localized selective emitter regions. Additional conductive ink can be applied that does not fire through the antireflection coating for the current collection grid and for the continuous metal fingers that overlie the regions containing the fire through ink and the selective emitter regions.

According to one embodiment, this invention may include the use of inkjet printing and/or aerosol jet printing to deposit selective emitter regions and/or doped current collection fingers either before or after forming a shallow emitter over most of the front surface of the solar cell. After depositing a silicon nitride or other suitable antireflection layer, the current collection fingers and/or busbar can be deposited directly over the selective emitter regions.

One factor or parameter for a good or high quality laser fired contact can be the laser intensity on the wafer. The intensity is determined by laser power, pulse repetition frequency (PRF), the beam size on the wafer, and/or the like. We have obtained low contact resistance contacts (<0.5 ohm) in a 20 millimeter by a 20 millimeter area on a 19×19 laser fired spot array with Nd:YAG lasers at 1064 nanometers. For example, one laser we used for this application was 0.51 watts at 500 hertz, and the other one laser was 1.5 watt at 10 kilohertz. The pulse energies were 1.02 millijoules and 0.15 millijoules respectively. The contact spot size can range from about 40 to about 150 micrometers, for example.

A 124×124 spot array on a 125 millimeter by a 125 millimeter wafer can be laser fired simultaneously or in parallel, with a 1064 nanometer Nd:YAG laser with 250 watts to 1600 watts at 100 hertz. Higher contact density may use additional numbers of split laser beams and/or additional power. Parallel laser fired contacts may include any suitable wavelength, power, pulse repetition frequency, duration, and/or any other parameter corresponding to different lasers, optical systems, contact designs, and/or the like.

According to one embodiment, it can take about 10 seconds or longer to make laser fired contacts on a 125 millimeter by a 125 millimeter wafer with flying mode using galvanometers and/or a moving stage. Laser processing in series may limit the speed and/or accuracy, such as due to acceleration and/or deceleration at each line or and/or point. The accuracy of flying mode can be less than desired. The parallel laser fired contacts can reduce the process time to less than about 1 second (a 10 fold increase or greater). The accuracy can also be improved since the beam and/or wafer do not need to be moved. Desirably, a shape of the laser beam can be controlled in a suitable pattern and/or output, such as a tophat and/or the like. Desirably, but not necessarily; beam shaping can be done without additional beam shaper components and/or assemblies.

Laser parallel processing techniques may include any suitable action or steps to modulate the laser beam distribution on a relatively large area on a wafer. The laser beam distribution can be modulated to a two-dimensional pattern (array), a one-dimensional pattern (line), and/or the like.

According to one embodiment, the modulation may include forming a plurality of small discrete spots on the wafer. The beam modulation can be achieved by an imaging system following a diffractive optic and/or a micro lens array.

According to one embodiment, the modulation may include a one dimensional process, such as spanning or crossing a width or a partial width of a solar cell and/or multiple solar cells. A relatively lower power laser can be used with a one dimensional spot array and combined with a one dimensional scanner and/or a one dimensional stage. For example, a 13 watt, 100 hertz laser power can be used with a 125 millimeter wafer. Multiple laser configurations are within the scope of this invention.

Other suitable modulations are also within the scope of this invention, such as a partial area process. A lower power laser process may include a partial area or a partial line with a two dimensional scanner and/or a two dimensional stage. In the alternative, a higher power laser fires all the contacts for a one or more solar cells at the same time.

According to one embodiment, this invention may include parallel laser firing contacts with an imaging system following a diffractive grating and/or a micro lens array. This invention may include parallel laser firing contacts on the whole area of a silicon wafer, parallel laser firing contacts on a line combined with one dimensional motion, parallel laser firing contacts on partial area or partial line combined with two dimensional motion, and/or the like. Parallel laser firing contacts may use any suitable laser with sufficient power and a sufficient wavelength. A suitable laser may include a solid state laser, a fiber laser, an excimer laser, a carbon dioxide (CO₂) laser, and/or the like.

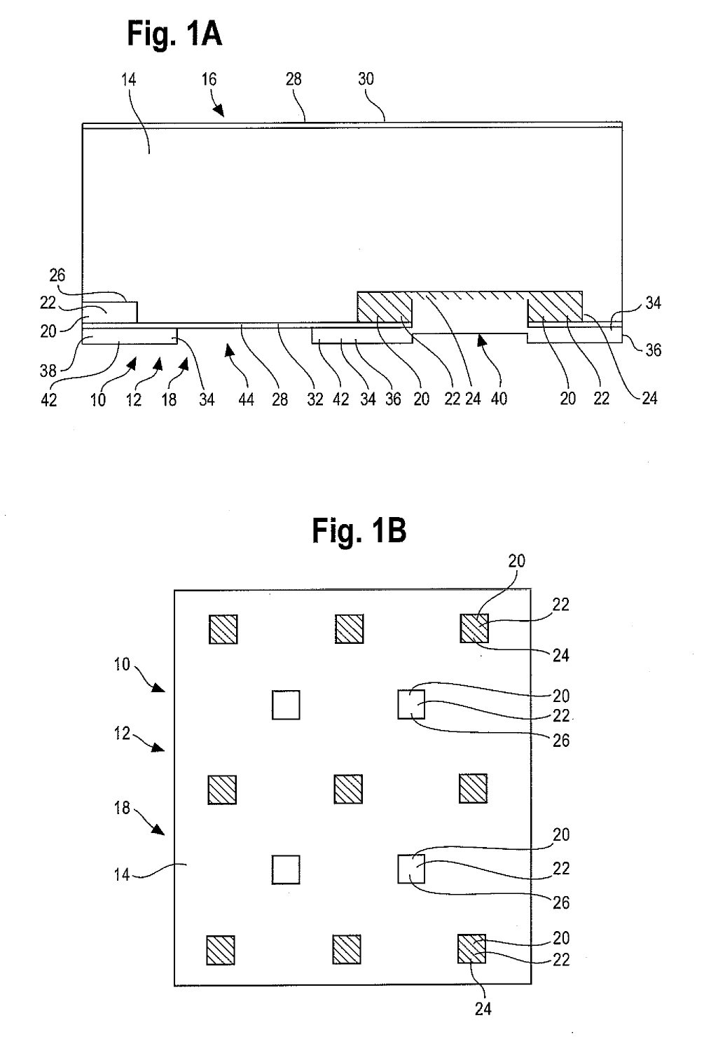

FIG. 1A illustrates a partial side sectional view of a back-contact photovoltaic cell 12, according to one embodiment. A photovoltaic cell 10 may be a back-contact photovoltaic cell 12, such as without contacts on a front or incident side. The back-contact photovoltaic cell 12 includes a doped wafer 14. The doped wafer 14 has a front surface 16 opposite a back surface 18. One suitable doped wafer 14 is a p-type float zone silicon wafer with a thickness of about 100 micrometers and a resistivity in the range of 0.1 to 20 ohm-centimeter.

The doped wafer 14 can be treated to form thermally diffused regions 20, such as using n⁺⁺ doping ink and p⁺⁺ doping ink applied by an inkjet printer and then thermally diffused into the doped wafer 14. The doping inks and diffusion processes form highly doped regions 22, such as first highly doped regions 24 (from a n⁺ dopant) and second highly doped regions 26 (from a p⁺ dopant). The highly doped regions 22 may be about 0.1 to about 10 micrometers thick.

A passivation layer 28 covers a portion of the photovoltaic cell 10. The passivation layer 28 can form a front passivation layer 30 and/or a back passivation layer 32. The passivation layer may be silicon nitride and have a thickness of about 0.1 micrometers, for example.

The back surface 18 may also include a network of conductors 34, such as a first conductor 36 and a second conductor 38. The first conductor 36 corresponds to the first highly doped regions 24 and can be electrically joined to the first highly doped regions 24 by a contact 40. The second conductor 38 corresponds to the second highly doped regions 26 and can be electrically joined to the second highly doped regions 26 by a contact 40. The network of conductors 34 may include a layer of silver metal having a thickness of about 2 micrometers thick, for example. The network of conductors 34 may form interdigitated fingers 42 with a gap 44 between the interdigitated fingers 42. The contacts 40 may be laser fired and form a crater or depression of about 2 micrometers deep or less in the back surface 18.

The major processing steps used to produce the photovoltaic cell 10 of FIG. 1 may include inkjet printing the doping inks and thermally diffusing the dopants to form the highly doped regions 22. The passivation layer 28 may be applied to both sides, such as by plasma enhanced chemical vapor deposition in a multi-chamber system. The network of conductors 34 may be inkjet printed on the passivation layer 28 and then laser fired to form the contacts 40. Other suitable processing steps may include texturing, annealing, laser ablation, cleaning, testing, and/or the like.

FIG. 1B illustrates a rear planar view of the back-contact photovoltaic cell 12 of FIG. 1A, according to one embodiment. The photovoltaic cell 10 includes the doped wafer 14 with the back surface 18, as described above. FIG. 1B shows the photovoltaic cell of FIG. 1A with the passivation layer 28 (not shown) and the network of conductors 34 (not shown) removed or prior to forming. The thermally diffused regions 20 and the highly doped regions 22 are viewed as forming a matrix, a grid, an array, and/or the like of the first highly doped regions 24 and the second highly doped regions 26. The n⁺⁺ dopant ink forms the first highly doped regions 24 and the p⁺⁺ dopant ink forms the second highly doped regions 26. The highly doped regions 22 may have a surface area of about 200 micrometers by about 200 micrometers in a generally rectangular shape, a generally square shape, a generally circular shape with a diameter of about 200 micrometers, and/or the like. The distance between the same kind and/or type of regions can be about 2 millimeters and the distance between the different kind and/or type of regions can be about 1.4 millimeters, for example.

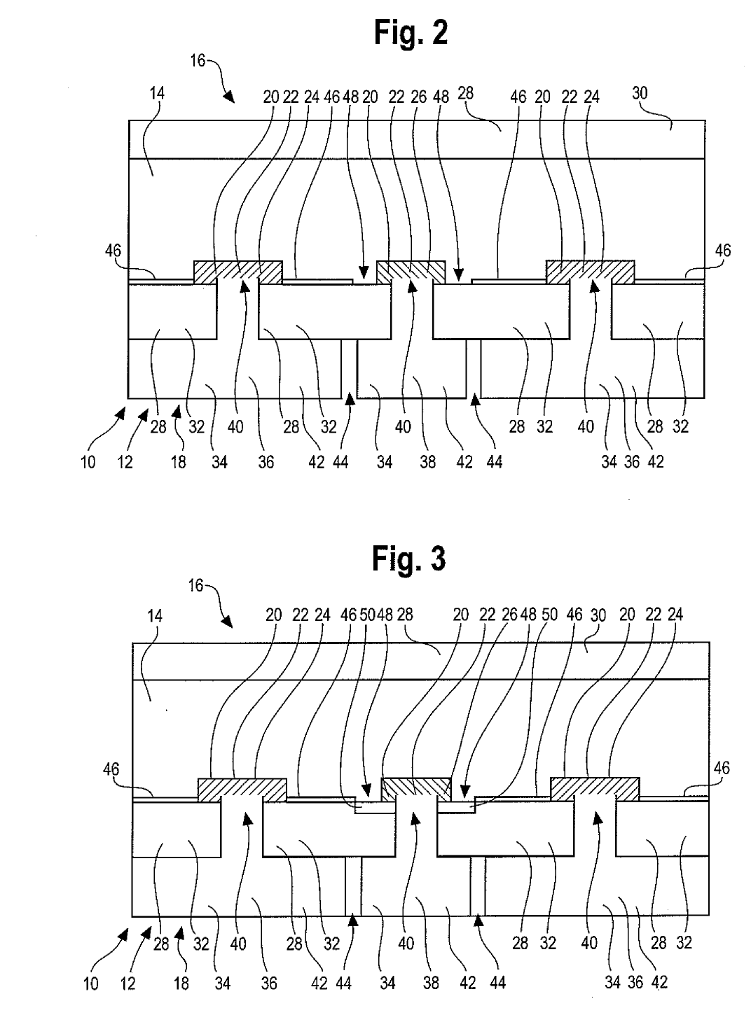

FIG. 2 illustrates a partial side sectional view of a back-contact photovoltaic cell 12 with a shallow emitter 46, according to one embodiment. The photovoltaic cell 10 includes a doped wafer 14 with a front surface 16 and a back surface 18. Thermally diffused regions 20 and highly doped regions 22 can be disposed on the back surface 18, such as to form first highly doped regions 24 and second highly doped regions 26. At the same time as forming the first highly doped regions 24, the shallow emitter 46 can be formed, such as over the remaining portion of the back surface 18. The shallow emitter 46 may not extend fully to the second highly doped regions 26, such as to form or make an isolation gap 48. In the alternative, the isolation gap 48 may be omitted.

A passivation layer 28 may be applied to the doped wafer 14, such as to form a front passivation layer 30 and a back passivation layer 32. The front passivation layer 30 may be silicon nitride having a thickness of about 0.08 micrometers. The back passivation layer 32 may be silicon oxide having a thickness of about 0.1 micrometers. In the alternative, the back passivation layer may be thicker than about 0.1 micrometers to assure electrical isolation between the second conductor 38 that contacts the second highly doped regions 26 and the shallow emitter 46 that covers most of the back surface. A network of conductors 34 may be disposed on the back passivation layer 32 and include a first conductor 36 and a second conductor 38.

Contacts 40 electrically connect the first highly doped regions 24 with the first conductor 36 and the contacts also electrically connect the second highly doped regions 26 with the second conductor 38. The network of conductors 34 may include interdigitated fingers 42 with gaps 44 between the interdigitated fingers 42.

The major processing steps used to produce the photovoltaic cell 10 of FIG. 2 may include inkjet printing the p⁺⁺ doping inks and using rapid thermal processing to form the second highly doped regions 26. The process may include inkjet printing n⁺⁺ doping inks and shallow emitter inks followed by a rapid thermal process to form the first highly doped regions 24 and/or the shallow emitter 46. The process may also include laying down the passivation layers 28 by their respective precursor compounds. The process may also include aerosol jet printing the network of conductors 34 and laser firing the contacts 40.

FIG. 3 illustrates a partial side sectional view of a back-contact photovoltaic cell 12 with a shallow emitter 46, according to one embodiment. The photovoltaic cell 10 of FIG. 3 structurally differs from the cell of FIG. 2 by the addition of an isolation layer 50, such as printed with an isolation ink to mask or block the shallow emitter ink from contacting the dopant of the opposite conductivity type.

The major processing steps used to produce the photovoltaic cell 10 of FIG. 3 may include inkjet printing the n⁺⁺ doping inks, the p⁺⁺ doping inks, and/or the isolation inks. Diffusion processing can form the highly doped regions 22 and the shallow emitter 46. The process may also include laying down the passivation layers 28 by their respective precursor compounds. The process may also include inkjet printing the network of contacts 34 and laser firing the contacts 40.

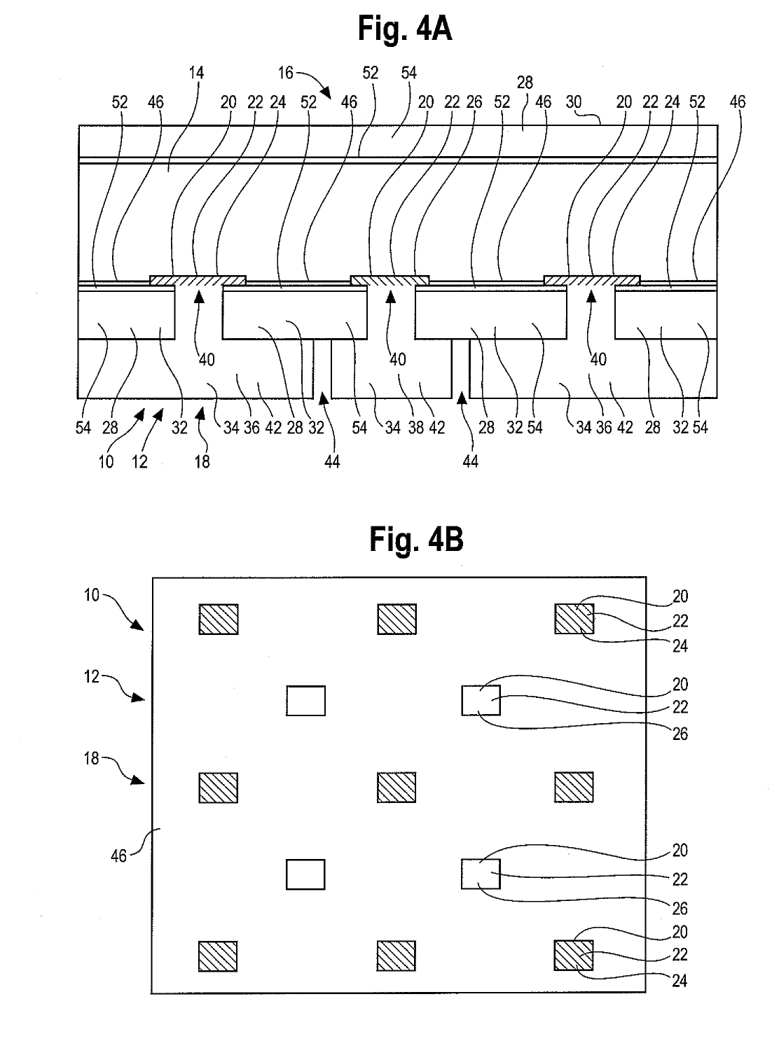

FIG. 4A illustrates a partial side sectional view of another back-contact photovoltaic cell 12 with a shallow emitter 46, according to one embodiment. The photovoltaic cell 10 has a doped wafer 14 with a front surface 16 and a back surface 18. The doped wafer 14 has thermally diffused regions 20 and highly doped regions 22, such as a plurality of first highly doped regions 24 and a plurality of second highly doped regions 26. The photovoltaic cell 10 also includes a shallow emitter 46.

The photovoltaic cell 10 of FIG. 4A differs from the cells described above in that a passivation layer 28 with a front passivation layer 30 and a back passivation layer 32 each includes more than one layer or strata. The passivation layer 28 includes a first passivation layer 52 and a second passivation layer 54. The first passivation layer 52 may be undoped amorphous silicon, for example. The second passivation layer 54 may be silicon nitride having a thickness of about 80 micrometers, for example. The photovoltaic cell 10 includes a network of conductors 34 with a first conductor 36 and a second conductor 38. Contacts 40 electrically connect the highly doped regions 22 and the network of conductors 34. The network of conductors 34 may include interdigitated fingers 42 with a gap 44 between the interdigitated fingers 42.

The major processing steps used to produce the photovoltaic cell 10 of FIG. 4A may include inkjet printing the n′ doping inks and the p′ doping inks followed by thermally diffusing the doping inks to form the highly doped regions and/or the shallow emitter. The process may also include adding the passivation layers 52 and 54 before inkjet printing the network of conductors 34. The contacts 40 can be laser fired.

FIG. 4B illustrates a rear planar view of the back-contact photovoltaic cell 12 with the shallow emitter 46 of FIG. 4A, according to one embodiment. The space between the highly doped regions 22 of the same type can be about 1 millimeter and the distance between the highly doped regions of the different kinds of regions can be about 0.7 millimeters, for example.

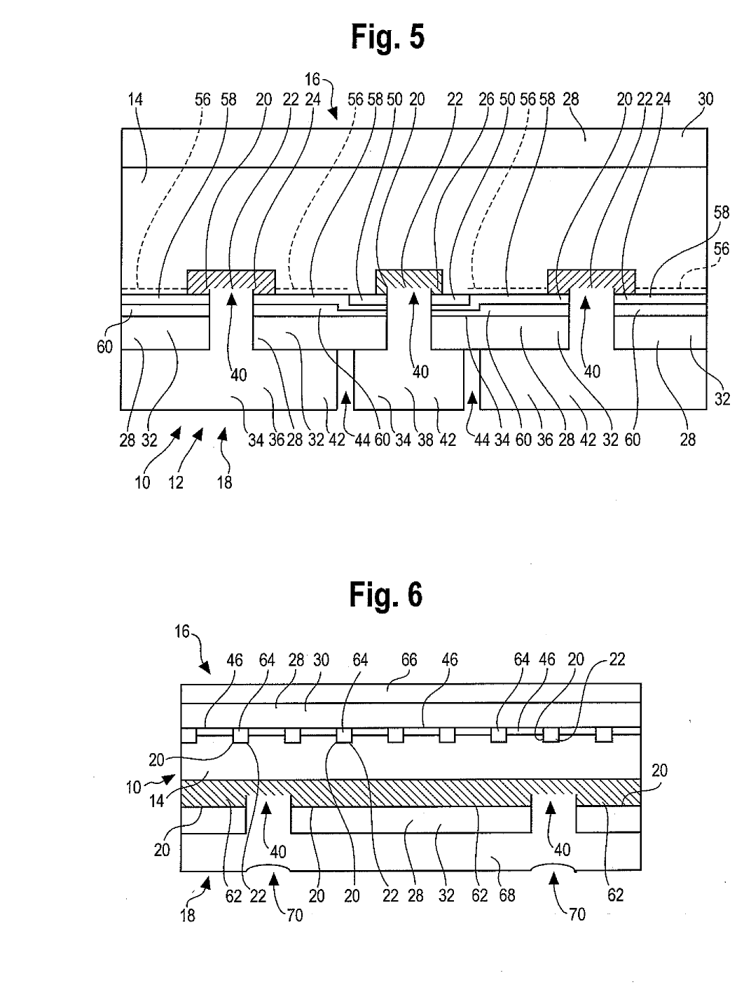

FIG. 5 illustrates a partial side sectional view of a back-contact photovoltaic cell 12 with an inversion layer 56, according to one embodiment. The photovoltaic cell 10 includes a doped wafer 14 with a front surface 16 and a back surface 18. The doped wafer 14 includes thermally diffused regions 20 and highly doped regions 22, such as first highly doped regions 24 and second highly doped regions 26. In this embodiment, an inversion layer 56 can be formed or induced into the doped wafer 14.

The inversion layer 56 includes a first layer of the inversion layer structure 58 and a second layer of inversion layer structure 60. The first layer of the inversion layer structure 58 can be applied to the back surface 18 and may include undoped amorphous silicon having a thickness of about 10 nanometers. An isolation ink may also be applied such as to form an isolation layer 50 to electrically isolate and/or insulate the highly doped regions 22 of the same conductivity type as the doped wafer 14. The second layer of the inversion layer structure 60 can be applied over the first layer of the inversion layer structure 58 and may include a highly doped amorphous silicon material having a thickness of about 20 nanometers. The second layer of the inversion layer structure 60 can have a conductivity type opposite the doped wafer 14.

The photovoltaic cell 10 may also include a passivation layer 28, such as a front passivation layer 30 and a back dielectric layer 32. The back dielectric 32 layer may include silicon oxide having a thickness of about 100 nanometers. A network of conductors 34 can be applied over the back dielectric layer 32. The network of conductors 34 may include a first conductor 36, such as silver having a thickness of about 1 micrometer. The network of conductors 34 may include a second conductor 38, such as aluminum having a thickness of about 1 micrometer. The network of conductors 34 may include interdigitated fingers 42 with a gap 44 between the interdigitated fingers 42 by the first conductor 36 and the second conductor 38.

The major processing steps used to produce the photovoltaic cell 10 of FIG. 5 may include inkjet printing the n⁺⁺ doping inks, the p⁺⁺ doping inks, and/or the isolation inks followed by thermally diffusing the doping inks to form the highly doped regions 22. The process may also include cleaning the front surface 16 and the back surface 18 and depositing the passivation layer 28. The process may also include inkjet printing the network of conductors 34 and laser firing the contacts 40.

FIG. 6 illustrates a partial side sectional view of a photovoltaic cell 10, according to one embodiment. The photovoltaic cell 10 of FIG. 6 differs from the cells discussed above since it includes front-contacts and back-contacts. The photovoltaic cell 10 includes a doped wafer 14 with a front surface 16 and a back surface 18. The doped wafer 14 includes thermally diffused regions 20 and highly doped regions 22. The highly doped regions 22 include fingers 64, such as on the front surface 16. The photovoltaic cell 10 also may include a shallow emitter 46 between the fingers 64, such as including phosphorus. A back surface field region 62 may be applied on the back surface 18, such as including boron.

The photovoltaic cell 10 includes a passivation layer 28, such as made of silicon nitride and having a front passivation layer 30 and a back passivation layer 32. A current collection grid 66 can be applied over the front passivation layer 30, such as including a silver frit or paste that can be thermally fired through the passivation layer 30. The current collection grid 66 generally includes an array or screen of conducting material applied over the front surface 16. The current collection grid 66 is shown in FIG. 6 in cross section and is not a solid or discrete layer on the front surface 16. A sheet conductor 68 can be applied over the back passivation layer 32, such as including aluminum. The contacts 40 can electrically connect the thermally diffused regions 20 with the sheet conductor 68. The contact 40 can form a dimple or a depression 70.

The major processing steps used to produce the photovoltaic cell 10 of FIG. 6 may include aerosol jet printing the fingers 64, the shallow emitter 46, and/or the back surface field region 62 with inks and/or dilute inks. The process may also include diffusing the fingers 64, the shallow emitter 46, and/or the back surface field region 62. A cleaning step using hydrochloric and/or hydrofluoric acid removes unwanted or undesired portions or particles. The passivation layer 28 can be applied to both sides. Aerosol jet printing can deposit or form the fire through current collection grid 66 and the sheet conductor 68. The process may include a rapid thermal processing step, such as to electrically connect the fingers 64 with the current collection grid 66. The process may include laser firing the contacts 40.

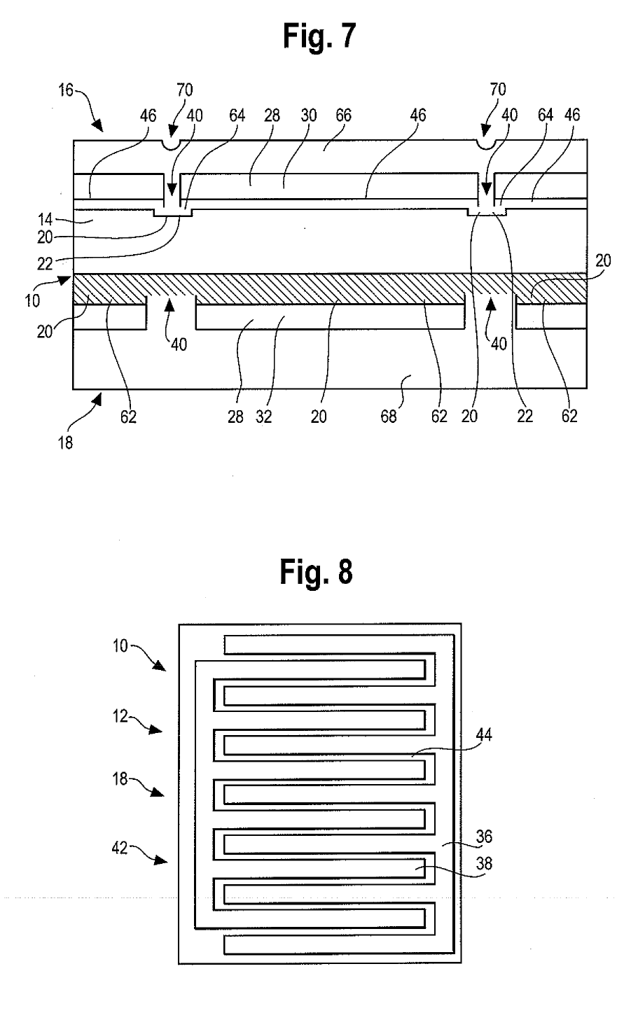

FIG. 7 illustrates a partial side sectional view of a photovoltaic cell 10, according to one embodiment. The photovoltaic cell 10 includes a doped wafer 14 having a front surface 16 and a back surface 18. The doped wafer 14 includes thermally diffused regions 20 and highly doped regions 22. A shallow emitter 46 may connect the fingers 64 and/or the highly doped regions 22 on the front surface 16, such as by using phosphorus dopant. A back surface field region 62 may be applied to the back surface 18, such as by using boron. A passivation layer 28 may form a front passivation layer 30 and a back passivation layer 32, such as by using silicon nitride. A current collection grid 66 may be applied over the front passivation layer 30 and electrically connect to the fingers 64 by contacts 40, such as laser fired silver contacts forming a depression 70. A sheet conductor 68 may be applied over the back passivation layer 32 and electrically connect to the back surface field region 62 by contacts, such as by laser fired silver and/or aluminum contacts.

The major processing steps used to produce the photovoltaic cell 10 of FIG. 7 may include non-contact printing n⁺⁺ inks for the fingers 62 and the shallow emitter 46 on the front surface 16. The process may also include non-contact printing p⁺ ink for the back surface field region 62. A diffusion step forms the highly doped regions 22, the shallow emitter 46, and/or the back surface field regions 62. A cleaning step with hydrofluoric acid removes glasses. The passivation layer 28 can be applied to both sides. Non-contact printing can deposit or form the current collection grid 66 and the sheet conductor 68. The process may include laser firing the contacts 40 through the passivation layer 28.

FIG. 8 illustrates a rear planar view of a network of conductors 34, according to one embodiment. The photovoltaic cell 10 may be a back-contact photovoltaic cell 12. The network of conductors 34 can be disposed on the back surface 18 and can include a first conductor 36 and a second conductor 38. The network of conductors 34 forms interdigitated fingers 42 with a gap 44 between the interdigitated fingers 42.

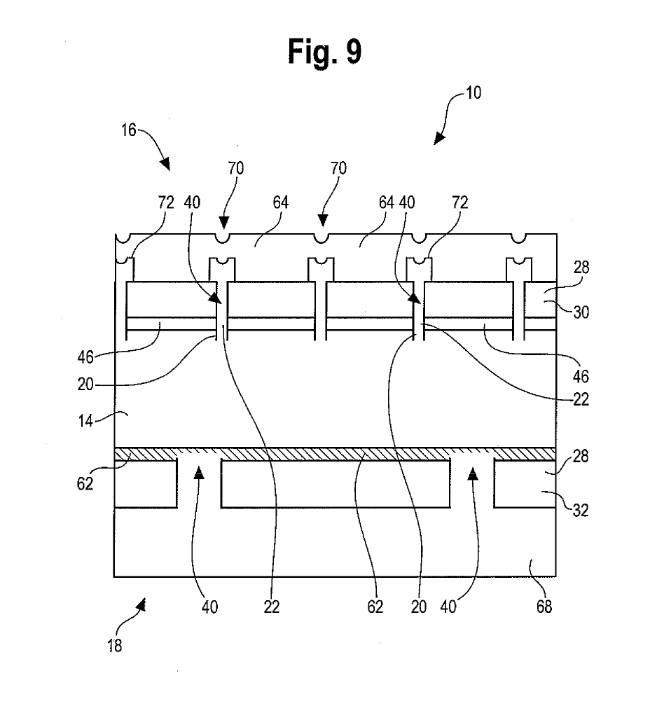

FIG. 9 illustrates a partial side sectional view of a photovoltaic cell 10, according to one embodiment. The photovoltaic cell 10 includes a doped wafer 14 with a front surface 16 and a back surface 18. The wafer 14 includes laser-diffused regions 20 and highly doped regions 22. The wafer also includes a passivation layer 28, such as a front passivation layer 30 and a back dielectric or passivation layer 32. The photovoltaic cell 10 also includes contacts 40, such as laser fired contacts on the front surface 16 and the back surface 18. The photovoltaic cell also includes a shallow emitter 46 and a back surface field region 62. Fingers 64 can collect the current on the front surface 16 and a sheet conductor 68 can collect the current on the back surface 18. The photovoltaic cell also includes depressions 70 and doping ink 72, such as for forming the contacts.

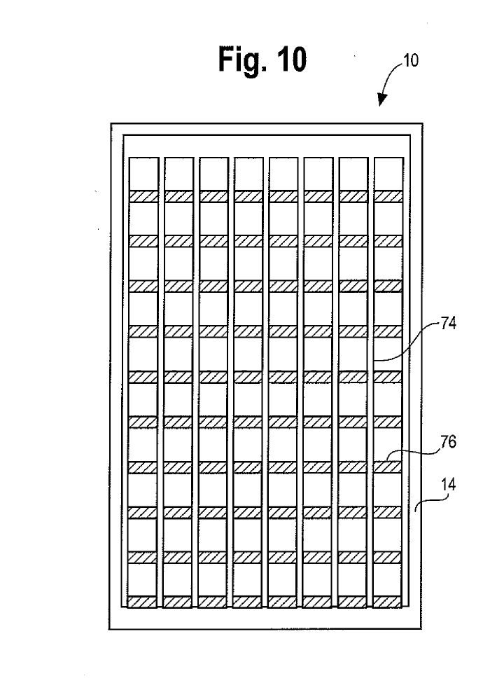

FIG. 10 schematically illustrates a wafer 14 with selective emitter regions 74 and current collection fingers 76, according to one embodiment. The selective emitter regions 74 form a generally parallel set of lines coming from a trunk or a main line (busbar). The current collection fingers 76 are disposed in another generally parallel set of lines arranged generally perpendicular to the selective emitter regions 74.

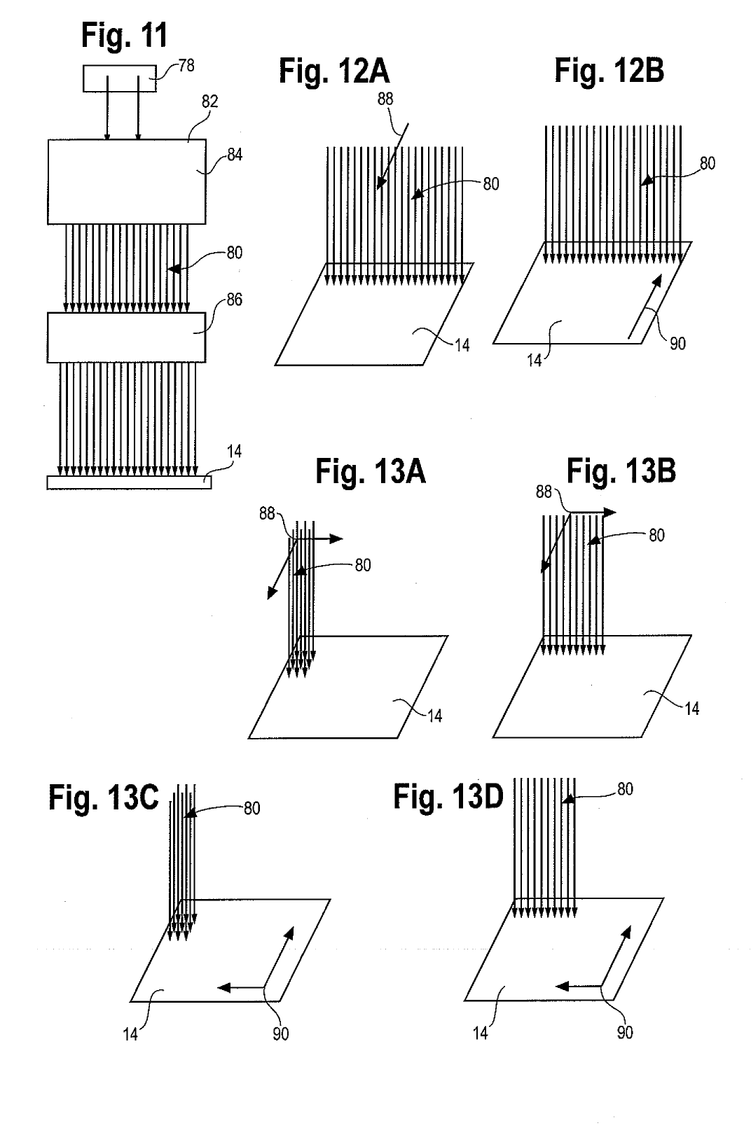

FIG. 11 schematically illustrates an apparatus used for parallel laser firing contacts 40 (not shown) on a wafer 14, according to one embodiment. The apparatus includes a laser 78, producing one or more beams into and/or through a diffractive grating 82 or a microlens array 84, such as to produce multiple laser beams 80. The multiple laser beams 80 may pass through an imaging system 86 before hitting the wafer 14.

FIG. 12A schematically illustrates a one dimensional scan for parallel laser firing contacts 40 (not shown) on a wafer 14 with multiple beams 80, according to one embodiment. The multiple beams 80 form a line or a segment across the wafer 14 and move with respect to the wafer 14 in a direction shown by a scan direction arrow 88.

FIG. 12B schematically illustrates a one dimensional stage for parallel laser firing contacts 40 (not shown) on a wafer 14 with multiple beams 80, according to one embodiment. The multiple beams 80 form a line or a segment across the wafer 14 and the wafer 14 moves with respect to the multiple beams 80 in a direction shown by a stage direction arrow 90.

FIG. 13A schematically illustrates a two dimensional scan for parallel laser firing contacts 40 (not shown) on a wafer 14 with multiple beams 80, according to one embodiment. The multiple beams 80 form an array or a grid across a portion of the wafer 14 and move with respect to the wafer 14 in directions shown by scan direction arrows 88, such as generally at right angles with respect to each other.

FIG. 13B schematically illustrates a two dimensional scan for parallel laser firing contacts 40 (not shown) on a wafer 14 with multiple beams 80, according to one embodiment. The multiple beams 80 form a line or a segment across a portion of the wafer 14 and move with respect to the wafer 14 in directions shown by scan direction arrows 88, such as generally at right angles with respect to each other.

FIG. 13C schematically illustrates a two dimensional stage for parallel laser firing contacts 40 (not shown) on a wafer 14 with multiple beams 80, according to one embodiment. The multiple beams 80 form an array or a grid across a portion of the wafer 14 and the wafer 14 moves with respect to the multiple beams 80 in directions shown by stage direction arrows 90, such as generally at right angles with respect to each other.

FIG. 13D schematically illustrates a two dimensional stage for parallel laser firing contacts 40 (not shown) on a wafer 14 with multiple beams 80, according to one embodiment. The multiple beams 80 form a line or a segment across a portion of the wafer 14 and the wafer 14 moves with respect to the multiple beams 80 in directions shown by stage direction arrows 90, such as generally at right angles with respect to each other. Combinations of scanning and a moving stage are within the scope of this invention.

According to one embodiment, this invention may include a back-contact photovoltaic cell. The cell may include a doped wafer of semiconductor material having a front surface and a back surface. The doped wafer may include any suitable semiconductor material, such as silicon, germanium, gallium arsenide, silicon germanium, gallium indium arsenide, indium antimonide, other semiconductors, and/or the like. The semiconductor material may include any suitable process or manufacturing steps, such as directional solidification, directional crystallization, float zone processes, Czochralski processes, and/or the like. Regarding silicon, suitable forms of silicon may include monocrystalline silicon, near monocrystalline silicon, multicrystalline silicon, geometric multicrystalline silicon, and/or the like.

The doped wafer may include any suitable size and/or shape. The doped wafer may include a front surface and a back surface disposed at least generally opposite each other. The doped wafer desirably includes a generally planar form or shape with a thickness much less than a length and/or a width. The shape of the wafer may include any suitable combination of rectilinear segments and/or arcuate segments, such as a generally square shape, a generally rectangular shape, a generally circular shape, and/or the like.

The doped wafer may include any suitable type of dopant and/or suitable concentration of dopant. A dopant or a doping agent broadly refers to an impurity element or compound added to a crystal lattice and/or a semiconductor lattice in relatively low concentrations, such as to alter or change electrical properties of the semiconductor. Without being bound by theory, addition of a dopant to a semiconductor material may shift a Fermi level within the material, such as to result in a material with predominantly negative (n-type) charge carriers or predominantly positive (p-type) charge carriers depending on the dopant species. The doped wafer may include any suitable conductivity type, such as n-type and/or p-type.

Suitable dopants for the doped wafer in the case of silicon may include boron, aluminum, gallium, indium, phosphorus, arsenic, antimony, and/or the like. Suitable concentrations of the dopant in the wafer may include between about 7×10¹⁴ atoms per cubic centimeter and about 8×10¹⁶ atoms per cubic centimeter for n-type dopants (such as phosphorus) in silicon and about 2×10¹⁵ atoms per cubic centimeter and about 3×10¹⁷ atoms per cubic centimeter for p-type dopants (such as boron) in silicon, and/or the like.

The doped wafers may include any suitable resistivity, such as between about 0.1 ohm-centimeter to about 20 ohm-centimeter, between about 0.5 ohm-centimeter to about 5 ohm-centimeter, and/or the like. One suitable doped wafer may include p-type doped silicon with a thickness of about 100 micrometers.

The front surface generally corresponds to the surface or orientation for receiving incident light when used in a solar panel or a solar module. The back surface generally corresponds to the surface opposite the front surface.

According to the same embodiment, the cell may also include a plurality of first highly doped regions disposed on or with respect to the back surface and having a first conductivity type. Plurality broadly refers to multiples of or more than one of an item or a unit. The first highly doped regions may include any suitable material, size, shape, conductivity type, and/or concentration. The dopant of the first highly doped region may include any of the materials discussed above regarding dopants for the doped wafer. The highly doped regions may have a size of between about 10 micrometers to about 1,000 micrometers, between about 50 micrometers to about 400 micrometers, about 200 micrometers, and/or the like.

The highly doped regions may be generally square, generally rectangular, generally triangular, generally round, and/or the like. The highly doped regions may include n-type and/or p-type dopants. The highly doped regions may cover any suitable percentage of the back surface, such as between about 0.5 percent and about 50 percent, between about 2 percent and about 10 percent, and/or the like. The highly doped regions may be spaced from each other at any suitable distance, such as between about 0.1 millimeters and about 10 millimeters, between about 0.3 millimeter and about 2 millimeters, and/or the like.

The highly doped regions may be disposed in any suitable pattern, such as a grid, a matrix, an array, and/or the like. The highly doped regions may include any suitable depth, such as after diffusion into the doped wafer of between about 0.01 micrometers and about 10 micrometers, between about 0.1 micrometers and about 1 micrometer, about 0.5 micrometers, and/or the like. The highly doped regions may be formed by any suitable process, such as thermal diffusion, rapid thermal processing, and/or the like. The highly doped regions may include thermally diffused regions.

Suitable concentrations of the dopant near the surface of the highly doped regions may include between about 5×10¹⁸ atoms per cubic centimeter and about 2×10²¹ atoms per cubic centimeter of an n-type dopant (such as phosphorus) in silicon, between about 8×10¹⁸ atoms per cubic centimeter and about 1.6×10²¹ atoms per cubic centimeter of a p-type dopant (such as boron) in silicon, and/or the like. The dopant source for the highly doped regions may be applied by or formed by any suitable process or device, such as contact printing, screen printing, non-contact printing, inkjet printing, aerosol jet printing, and/or the like. The sheet resistance of the highly doped regions may be between about 5 ohms per square and about 50 ohms per square, and about 20 ohms per square, and/or the like. The depth of the heavily doped region, the dopant concentration and the doping profile can be adjusted to obtain the desired sheet resistance.

According to the same embodiment, the cell may also include a plurality of second highly doped regions disposed with respect to the back surface and having an opposite conductivity type from the first conductivity type. The second highly doped regions may include all the features and/or the characteristics of the first highly doped regions as discussed above except having a different or opposite conductivity type. Desirably, the second highly doped regions intersperse with or are scattered among the first highly doped regions, such as to form alternating rows and/or columns. The arrangement of first highly doped regions and the second highly doped regions may be described as like a checker board pattern.

A ratio of a distance between a first highly doped region of one type and a second highly doped region of another type to a distance between a first highly doped region of one type and a second highly doped region of the same type may include any suitable number, such as between about 0.1 to about 1.0, between about 0.5 to about 0.8, about 0.7, and/or the like. This ratio can be expressed as the distance between different regions over the distance between same regions.

Desirably, the first highly doped regions and the second highly doped regions form contacts, such as useful for photovoltaic cells in solar panels and/or solar modules. One highly doped region will form a p/n junction while the other type will form an ohmic contact to the base material of the silicon wafer. Forming the p-n junction and the ohmic contact on the back side offers increased front surface area for collection of energy, such as collecting a portion of the electromagnetic spectrum from the sun on the front side. Additionally, forming the p-n junction on the back side may reduce processing steps and/or manufacturing costs.

Noncontact printing, inkjet printing, aerosol jet printing, and/or the like may be performed in any suitable conditions, such as in an inert atmosphere, in a reducing atmosphere, in an oxidizing atmosphere, and/or the like. The printing process may include elevated temperatures for the wafer, the substrate, the ink, the printing chamber, and/or the like. Without being bound by theory elevated temperatures may assist in dry solvents and/or setting inks, for example. Elevated temperatures may include at least about 20 degrees Celsius, at least about 50 degrees Celsius, at least about 100 degrees Celsius, at least about 250 degrees Celsius, at least about 500 degrees Celsius, and/or the like.

According to the same embodiment, the cell may include a passivation layer disposed over at least a portion of each the plurality of first highly doped regions, the plurality of second highly doped regions, and/or the back surface. Optionally, the cell may also include a passivation layer disposed over the front surface. The passivation layer may include any suitable electrically insulating material or dielectric material that assures low surface recombination, such as amorphous silicon, silicon dioxide (silica), silicon nitride and/or the like.

The passivation layer may include any suitable thickness, such as between about 0.01 micrometers and about 10 micrometers, between about 0.1 micrometers and about 1 micrometer, about 0.1 micrometers, and/or the like. Desirably, the passivation layer uniformly covers the plurality of first highly doped regions, the plurality of second highly doped regions, and/or any exposed portions (not part of the highly doped regions) of the back surface. The passivation layer may be formed by any suitable process or device, such as plasma enhanced chemical vapor deposition, magnetron sputtering, hot-wire chemical vapor deposition, and/or the like. Suitable temperatures for forming the passivation layer may include between about 50 degrees Celsius and about 1,000 degrees Celsius, between about 150 degrees Celsius and about 400 degrees Celsius, and/or the like.

Additionally and/or optionally, the passivation layer may include at least two layers (composite), such as a layer of amorphous silicon against the doped wafer and a layer of silicon nitride over the amorphous silicon. Gradients between the passivation layers are within the scope of this invention, such as changing a composition with respect to a depth instead of discrete layers and/or boundaries. For simplicity in manufacture, cells with composite passivation layers may include composite passivation layers on the front surface as well. Desirably, the passivation layer forms a well passivated surface.

According to the same embodiment, the cell may include a network of conductors disposed with respect to or on the passivation layer and having a first conductor and a second conductor. Network broadly refers to an interconnected or interrelated group, web, system, and/or the like. Conductors broadly refer to any suitable material to facilitate or enable a flow of electric current, electrons, and/or the like. The conductors may include any suitable material, size, and/or shape. Silver, aluminum, platinum, copper, gold, and/or the like may be used as conductors. The conductors may be applied in any suitable thickness, such as between about 0.1 micrometers and about 10 micrometers, between about 1 micrometer and about 5 micrometers, about 2 micrometers, and/or the like.

Desirably, the first conductor aligns and/or overlays with the plurality of first highly doped regions and the second conductor aligns and/or overlays with the plurality of second highly doped regions. The conductors may cover any suitable portion of the back surface passivation layer, such as between about 1 percent and about 100 percent, between about 50 percent and 98 percent, about 90 percent, and/or the like. The gap or space between the conductors may include any suitable distance, such as between about 1 micrometer and about 1,000 micrometers, between about 10 micrometers and about 200 micrometers, about 80 micrometers, and/or the like.

The first conductor and the second conductor may generally parallel each other, such as to form interlocking or interdigitated fingers, for example. The fingers may extend from a trunk or a main line, such as disposed on a side and/or an edge of the cell. Other configurations of the first conductor and/or the second conductor are within the scope of this invention.

According to the same embodiment, the cell may include a plurality of contacts electrically connecting the first highly doped regions with the first conductor and electrically connecting the second highly doped regions with the second conductor. Contacts broadly refer to any suitable union or junction, such as to allow the flow of electrical current. The contacts may include any suitable size, shape, density (number per area), and/or the like. The contacts may include a size (effective diameter) of between about 10 micrometers and about 300 micrometers, between about 50 micrometers and about 150 micrometers, about 100 micrometers, and/or the like. The contacts may include any suitable depth into the doped wafer and/or the highly doped regions, such as between about 0.01 micrometers and about 10 micrometers, between about 0.1 micrometers and about 1.0 micrometer, about 0.5 micrometers, and/or the like.

The contacts may be point contacts. Generally, one or more contacts correspond to each of the highly doped regions. The contacts may be made in any suitable manner, such as laser firing, laser ablating vias before depositing the conductors, etching vias before depositing the conductors and/or the like. The contacts may include any suitable portion of the back surface, such as between about 0.1 percent and about 50 percent, between about 1 percent and about 10 percent, about 2 percent, and/or the like. The contacts may include a crater and/or a depression, such as on the back surface and extending through the passivation layer, into the highly doped region, and/or into the doped wafer. The crater may include any suitable depth, such as between about 0.01 micrometers and about 3 micrometers, between about 0.1 micrometer and about 1 micrometer, about 0.3 micrometers, and/or the like. The crater may be formed from the laser firing.

Laser fired contacts may include parallel laser fired contacts, such as splitting one or more laser beams into multiple beams to process or make additional contacts at the same and/or substantially the same time. The laser fired contacts may be formed by passing a laser beam through a diffractive grating and/or a microlens array to form multiple beams and optionally passing the multiple beams through an imaging system. Desirably, the imaging system provides multiple beams having a generally uniform intensity across an entire cross section, such as to produce contacts with even penetration into the wafer or the substrate. The laser beam may be split into any suitable number of beams, such as at least about 16, at least about 100, at least about 500, at least about 1,000, and/or the like. The multiple laser beams may have any suitable spacing, such as generally corresponding to at least some of the heavily doped regions. Optionally and/or alternatively, the multiple beams can be reshaped by the diffractive optic, the microlens array, the imaging system, and/or the like.

The multiple laser beams may form any suitable shape, such as a line, a segment, a grid, an array, and/or the like. The multiple laser beams may contact any suitable portion of a width of the wafer formed by a line of multiple beams, such as at least about 1 percent, at least about 20 percent, at least about 50 percent, at least about 75 percent, about 100 percent, and/or the like. In the alternative, the multiple laser beams may contact any suitable portion of the wafer formed by a perimeter of the multiple beams, such as at least about 1 percent, at least about 20 percent, at least about 50 percent, at least about 75 percent, about 100 percent, and/or the like. Any suitable intensity is possible for each multiple beam, such as to form a suitable contact.

Moving the multiple laser beams with respect to the wafer may be by any suitable device or system, such as by scanning (moving the beams) and/or a stage (moving the wafer). The motion may be one dimensional, two dimensional, three dimensional, and/or the like. Motions of two or more directions may be generally perpendicular with respect to each other.

According to one embodiment, the cell may include a shallow emitter just beneath the back surface and/or under the passivation layer. The shallow emitter may be disposed between the plurality of the first highly doped regions and the plurality of the second highly doped regions. Without being bound by theory, the shallow emitter may provide additional surface area with which to collect minority carriers. Just beneath broadly refers to being positioned and/or diffused into the doped wafer. The shallow emitted broadly includes a dopant and includes a region or area outside of the highly doped regions, such as to cover up to the entire remaining portion of the back surface.

The shallow emitter may include any suitable depth, such as between about 0.01 micrometers and about 1.0 micrometer; between about 0.05 micrometers and about 0.5 micrometers, about 0.2 micrometers, and/or the like. The shallow emitter may include any suitable concentration of dopant or dilute dopant, such as between about 10¹⁸ atoms per cubic centimeter and about 10²¹ atoms per cubic centimeter about 10²⁰ atoms per cubic centimeter, and/or the like, where the concentrations are at the surface. The sheet resistance associated with the shallow emitter can be between about 70 ohms per square and about 300 ohms per square, about 100 ohms per square, and/or the like. The depth of the shallow emitter, the dopant concentration and the doping profile can be adjusted to obtain the desired sheet resistance.

A ratio of the dopant concentration on or near the surface in the highly doped regions to the dopant concentration on or near the surface in the shallow emitter may include any suitable value, such as between about 20 to 1 and about 1.5 to 1, between about 10 to 1 and about 2 to 1, about 3 to 1, and/or the like. The ratio of the sheet resistance in the shallow emitter to the sheet resistance in the heavily doped regions can be any suitable value, such as between about 40 to 1 and about 1.5 to 1, between about 20 to 1 and about 3 to 1, about 10 to 1, and/or the like.

The shallow emitter may include any suitable conductivity type. Desirably, the shallow emitter may include a conductivity type opposite the doped wafer. Also desirably, the shallow emitter electrically connects and/or couples with the highly doped regions having the same conductivity type.

Additionally and/or optionally, the cell may include an isolation gap between the shallow emitter and the highly doped regions of the opposite conductivity type. The isolation gap may include any suitable distance or length, such as between about 5 micrometers and about 500 micrometers, between about 10 micrometers and about 200 micrometers, about 100 micrometers, and/or the like. The isolation gap may prevent recombining of carriers of opposite types at the intersection or boundary between the shallow emitter and the highly doped regions of opposite conductivity type of the shallow emitter. The isolation gap may be formed from a region or part of the doped wafer. Generally, the isolation gap encircles or bounds a perimeter of the highly doped region, such as to form an annulus or other suitable border.

In the alternative, the cell may include an isolation layer between the shallow emitter and the highly doped regions of opposite conductivity type from the shallow emitter. The isolation layer may include any suitable non-conducting material, such as silicon dioxide, silicon nitride, and/or the like. The isolation layer may be applied before forming the shallow emitter, such as to mask or block the shallow emitter from contacting the highly doped regions of opposite conductivity type. The isolation layer may include any suitable thickness, such as between about 0.1 micrometers and about 100 micrometers, between about 0.5 micrometers and about 20 micrometers, about 2 micrometers, and/or the like. The isolation layer may have any suitable distance, such as discussed above with respect to the isolation gap.

According to one embodiment, the cell may include an inversion layer just beneath the back surface and the passivation layer. The inversion layer may offer the functionality and/or the capabilities of part of a p-n junction without having to diffuse the dopant into the substrate. Without being bound by theory, the inversion layer may be formed by an undoped layer, such as amorphous silicon and a highly doped layer having a conductivity type opposite the doped wafer over the undoped layer. The highly doped layer induces an emitter through the undoped layer and into a portion of the doped wafer, such as between the highly doped regions discussed above.

The undoped layer may include any suitable thickness, such as between about 0.005 micrometers and about 0.1 micrometers, between about 0.01 micrometers and about 0.05 micrometers, about 0.02 micrometers, and/or the like. The highly doped layer may include any suitable thickness, such as between about 0.01 micrometers and about 0.1 micrometers, about 0.03 micrometers, and/or the like.

Optionally and/or additionally as part of the inversion layer, an isolation gap or isolation layer may be disposed with respect to the undoped layer and the highly doped regions of the same conductivity type as the doped wafer (opposite the highly doped layer of the inversion layer).

The inversion layer may include and/or be induced by an undoped layer of an amorphous silicon alloy and a highly doped layer having a conductivity type opposite the doped wafer.

The photovoltaic cell of this invention may include other features and/or characteristics, such as an antireflective coating and/or textured surfaces.

According to one embodiment, the photovoltaic cells of this invention include an efficiency (energy supplied over energy produced) of at least about 15 percent, at least about 18 percent, at least about 20 percent, at least about 22 percent, and/or the like.

According to one embodiment, this invention may include a photovoltaic cell. This embodiment of a photovoltaic cell differs from those discussed above in that it may include front-contacts and back-contacts. A structure of the cell will be described below. As consistent through out this specification, any common language with respect to the cells discussed above may allow the reader to apply any and/or all of the features and/or the characteristics of that element discussed to this or other embodiments (such as to avoid repetition).

The cell may include a doped wafer of semiconductor material having a front surface and a back surface. The cell may also include a plurality of highly doped regions disposed with respect to the front surface and having a conductivity type opposite the doped wafer. The cell may also include a shallow emitter disposed between the plurality of highly doped regions and having a same conductivity type as the highly doped regions. The highly doped regions may sometimes be referred to as highly doped fingers.

According to the same embodiment, the cell may also include a back surface field region just beneath the back surface. The back surface filed region may provide an electrical path on the back side of the cell. The back surface field region can be formed either by a highly doped region having a same conductivity type as the doped wafer or by an undoped layer of an amorphous silicon alloy and a highly doped layer of a same conductivity type as the doped wafer.

The cell may also include a front passivation layer disposed with respect to the highly doped regions and the shallow emitter. The cell may also include a back passivation layer disposed with respect to the back surface field region.

According to the same embodiment, the cell may include a current collection grid disposed with respect to the front passivation layer and electrically connected to the highly doped regions. The current collection grid may be electrically connected in any suitable manner, such as laser fired contacts and/or thermal processing. Current collection grid broadly refers to any suitable device or configuration for electrical collection and/or distribution. The current collection grid may include one or more conductors, as discussed above.

According to the same embodiment, the cell may also include a conductor and/or a sheet conductor disposed with respect to the back passivation layer. The cell may also include a plurality of contacts electrically connecting the back surface field region with the conductor, such as laser fired contacts.

According to one embodiment, the cell may include a grid of selective emitter regions and current collection fingers disposed with respect to the front surface. Desirably, the selective emitter regions include a series of generally parallel lines. The current collection fingers may include a series of generally parallel lines generally perpendicular with respect to the selective emitter regions. The selective emitter regions and the current collection fingers may electrically contact each other at a plurality of intersections or junctions.

According to one embodiment, the cell may include a grid of selective emitter regions and current collection fingers disposed with respect to the front surface.

As used herein the terms “having”, “comprising”, and “including” are open and inclusive expressions. Alternately, the term “consisting” is a closed and exclusive expression. Should any ambiguity exist in construing any term in the claims or the specification, the intent of the drafter is toward open and inclusive expressions.

Regarding an order, number, sequence, and/or limit of repetition for steps in a method or process, the drafter intends no implied order, number, sequence, and/or limit of repetition for the steps to the scope of the invention, unless explicitly provided.

According to one embodiment, this invention may include a process of manufacturing back-contact photovoltaic cells. The process may include the step of applying a first dopant source to a portion of a back surface of a doped wafer of semiconductor material. The first dopant source has a first conductivity type.

Applying broadly may include any suitable action, such as printing, contact printing, screen printing, non-contact printing, inkjet printing, aerosol jet printing, brushing, coating, and/or the like. Dopant sources broadly include any suitable source or supply of the dopant atoms and/or molecules. Dopant sources may include inks, slurries, emulsions, pastes, powders, particles, nanoparticles, solutions, and/or the like. Dopant sources may include solvents, binders, flow modifiers, and/or the like. One suitable dopant source is a boron ink supplied from Filmtronics based in Butler, Pa., U.S.A. Another suitable dopant source is a phosphorus ink supplied from Cookson electronics based in Providence, R.I., U.S.A. Suitable inkjet printers include Dimatix DMP model from FujiFilm Dimatix based in Santa Clara, Calif., U.S.A. Suitable aerosol jet printers may include the M3D 300SL model from Optomec based in Albuquerque, N. Mex., U.S.A.

According to the same embodiment, the process may also include the step of applying a second dopant source to a different portion of the back surface of the doped wafer of semiconductor material. The second dopant source has an opposite conductivity type from the first conductivity type.

The process may also include the step of diffusing the first dopant source and/or the second dopant source into the doped wafer to form a plurality of first highly doped regions and/or a plurality of second highly doped regions respectively. Diffusing may include any suitable step to molecularly and/or atomically intersperse or spread the dopant into the substrate or the doped wafer (drive into). Thermal diffusion can be used for any suitable time (duration) and any suitable elevated temperature, such as at least about 700 degrees Celsius, at least about 900 degrees Celsius, at least about 1,200 degrees Celsius, and/or the like. Thermal processes may include a heat or ramp up time or period, a hold or dwell at temperature time or period, and/or a slow cool down time or period. Heating and cooling rates may include any suitable value, such as from degrees Celsius per minute to tens of degrees Celsius per second.

Optionally and/or additionally, rapid thermal annealing or processing may be used to diffuse materials. Rapid thermal processing includes a temperature change of at least about 20 degrees Celsius per second, at least about 100 degrees Celsius per second, and/or the like. Rapid thermal processing may offer shorter manufacturing times, reduced thermally caused defects, increased throughput, and/or the like. Rapid thermal processing may include heat transfer by convection, conduction, radiation, and/or the like. Rapid thermal processing may be for any suitable duration (heat up and cool down), such as between about 15 seconds and about 5 minutes, between about 30 seconds and 2 minutes, and/or the like.

The process may also include the step of cleaning the back surface. Cleaning broadly may include any suitable step to remove debris or prepare a surface for additional processing. Cleaning may include rinsing with water, rinsing with a solvent, chemical etching (acid and/or caustic), plasma etching, and/or the like.

According to the same embodiment, the process may include the step of laying a passivation layer over the back surface, the front surface, the plurality of first highly doped regions, and/or the plurality of second highly doped regions. Laying may broadly include any suitable action to form or deposit the passivation layer, such as chemical vapor deposition, plasma enhanced chemical vapor deposition, sputtering, magnetron sputtering, hot-wire chemical vapor deposition, and/or the like. Optionally and/or additionally, the step of laying the passivation layer may include forming more than one layers and/or a gradient, such as a layer of amorphous silicon and a layer of silicon nitride.

The process may also include the step of applying a network of conductors to a portion of the passivation layer, such as to form a first conductor and a second conductor. The network of conductors may be formed by conducting inks, such as containing aluminum, copper, silver, and/or the like. One suitable conductor ink is silver ink from Five Star Technologies based in Independence, Ohio, U.S.A.

The process may also include the step of forming contacts between the network of conductors and both the first highly doped regions and the second highly doped regions, such as to electrically connect the first highly doped regions with each other and to electrically connect the second highly doped regions with each other. The contacts may be formed by any suitable process, such as laser firing, thermal processing, rapid thermal processing, and/or the like. Laser firing may include single (series) beam laser firing or processing, such as with a scanning system or a motion stage. In the alternative, the laser firing may include multiple beam laser firing or processing, such as passing a laser beam through a diffractive optic or a microlens array to form multiple beams and optionally passing the multiple beams through an imaging system before contacting the wafer to make the contacts.

According to one embodiment, the step of applying the network of conductors may include forming interdigitated fingers and/or any other suitable structure.

According to one embodiment, the process may also include the step of applying a dilute dopant source of an opposite conductivity type to the doped wafer on the back surface between the plurality of the first highly doped regions and the plurality of the second highly doped regions. The process may also include the step of diffusing the dilute dopant source into the doped wafer to form a shallow emitter. Suitable dilute dopant sources may include phosphorus ink from Filmtronics based in Butler, Pa., U.S.A., for example.

Optionally and/or additionally, the process may also include the step of applying an isolation layer or assuring an isolation gap between the shallow emitter and highly doped regions of opposite conductivity type from the shallow emitter. The isolation layer may be formed from or by any suitable material, such as an isolation ink or paste. Suitable isolation inks may include silica coatings from Datec Coating Corporation based in Mississauga, Ontario, Canada, for example.

According to one embodiment, the process may also include the step of forming an inversion layer just beneath the back surface and the passivation layer. Forming an inversion layer may be done by any suitable combination of laying or forming layers. The step of forming an inversion layer may include the step of depositing an undoped layer of an amorphous silicon alloy on the back surface. The step of forming an inversion layer may also include the step of depositing a highly doped layer having a conductivity type opposite the doped wafer on the undoped layer.

According to one embodiment, this invention may include a process of manufacturing photovoltaic cells. The process may include the step of applying a dopant source to a portion of a front surface of a doped wafer of semiconductor material. The dopant source has a conductivity type opposite the doped wafer. The process may also include the step of applying a dilute dopant source having a conductivity type opposite the doped wafer to the remainder of the front surface of the doped wafer. The process may also include the step of applying a dopant source to a portion of a back surface of a doped wafer. The dopant source has the same conductivity type as the doped wafer.

According to the same embodiment, the process may also include the step of diffusing the dopant sources and/or the dilute dopant source into the doped wafer to form highly doped regions, a shallow emitter, and/or a back surface field region. The process may also include the step of laying a passivation layer over the highly doped regions, the shallow emitter, the front surface, the back surface and/or the back surface field region to form a front passivation layer and/or a back passivation layer. The process may also include the step of applying a current collection grid on the front passivation layer. The process may also include the step of applying a conductor on the back passivation layer. The process may also include the step of forming front-contacts between the highly doped regions and the current collection grid. The process may also include the step of forming back-contacts between the back surface field region and the conductor.

Desirably, but not necessarily, the steps of forming the front-contacts and/or forming the back-contacts may include laser firing contacts, such as parallel laser firing.

According to one embodiment, the process may further include the step of forming a grid of selective emitter regions and current collection fingers disposed with respect to the front surface.

According to one embodiment, the process may include the step of applying a dopant source to a portion of a front surface of the doped wafer comprises applying a doping ink over the front passivation layer, and the step of diffusing the dopant sources comprises laser firing the doping ink through the front passivation layer while optionally performing the step of forming front-contacts between the highly doped regions and the current collection grid.

### Example

A batch of solar cells were made by using a laser to fire an aluminum contact through a silicon nitride layer into an aluminum doped back surface field region. Surprisingly and unexpectedly the efficiencies were as high as 15.8 percent (energy converted over energy applied). The conventional control solar cells without laser fired contacts had an efficiency of 15.3 percent. The cells of this invention had a 3.3 percent relative increase in power over the conventional cells.

It will be apparent to those skilled in the art that various modifications and variations can be made in the disclosed structures and methods without departing from the scope or spirit of the invention. Particularly, descriptions of any one embodiment can be freely combined with descriptions or other embodiments to result in combinations and/or variations of two or more elements or limitations. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

What is claimed is:

1. A back-contact photovoltaic cell, the cell comprising:
a doped wafer of semiconductor material having a front surface and a back surface;
a plurality of first highly doped regions disposed with respect to the back surface and having a first conductivity type;
a plurality of second highly doped regions disposed with respect to the back surface and having an opposite conductivity type from the first conductivity type;
a passivation layer disposed over at least a portion of each of the plurality of first highly doped regions, the plurality of second highly doped regions, and the back surface;
a network of conductors disposed with respect to the passivation layer and having a first conductor and a second conductor; and
a plurality of contacts electrically connecting the first highly doped regions with the first conductor and electrically connecting the second highly doped regions with the second conductor.

2. The cell of claim 1, wherein the first highly doped regions and the second highly doped regions were formed by non-contact printing.

3. The cell of claim 2, wherein the non-contact printing comprises inkjet printing, aerosol jet printing, or jet dispensing.

4. The cell of claim 1, wherein the first highly doped regions and the second highly doped regions comprise thermally diffused regions.

5. The cell of claim 1, wherein the passivation layer was formed by plasma enhanced chemical vapor deposition, magnetron sputtering, or hot-wire chemical vapor deposition.

6. The cell of claim 1, wherein the network of conductors comprises interdigitated fingers.

7. The cell of claim 1, wherein the plurality of contacts comprises laser fired contacts.

8. The cell of claim 7, wherein the laser fired contacts comprise parallel laser fired contacts.

9. The cell of claim 1, further comprising a shallow emitter just beneath the back surface and the passivation layer, and the shallow emitter disposed between the plurality of the first highly doped regions and the plurality of the second highly doped regions.

10. The cell of claim 9, wherein the shallow emitter comprises the conductivity type opposite the doped wafer.

11. The cell of claim 9, further comprising an isolation layer or an isolation gap between the shallow emitter and highly doped regions of opposite conductivity type from the shallow emitter.

12. The cell of claim 1, wherein the passivation layer comprises at least two layers.

13. The cell of claim 13, wherein the passivation layer comprises a layer of amorphous silicon and a layer of silicon nitride.

14. The cell of claim 1, further comprising an inversion layer just beneath the back surface and the passivation layer.

15. The cell of claim 14, wherein the inversion layer is induced by an undoped layer of an amorphous silicon alloy and a highly doped layer having a conductivity type opposite the doped wafer.

16. A photovoltaic cell, the cell comprising:
a doped wafer of semiconductor material having a front surface and a back surface;
a plurality of highly doped regions disposed with respect to the front surface and having a conductivity type opposite the doped wafer;
a shallow emitter disposed between the plurality of highly doped regions and having a same conductivity type as the highly doped regions;
a back surface field region just beneath the back surface, the back surface field region is formed either by a highly doped region having a same conductivity type as the doped wafer, or by an undoped layer of an amorphous silicon alloy and a highly doped layer of a same conductivity type as the doped wafer;
a front passivation layer disposed with respect to the highly doped regions and the shallow emitter;
a back passivation layer disposed with respect to the back surface field region;
a current collection grid disposed with respect to the front passivation layer and electrically connected to the highly doped regions;
a conductor disposed with respect to the back passivation layer; and
a plurality of contacts electrically connecting the back surface field region with the conductor.

17. The cell of claim 16, wherein the plurality of contacts comprises laser fired contacts.

18. The cell of claim 17, wherein the laser fired contacts were made by:
passing a laser beam through a diffractive optic or a microlens array to form multiple beams; and
optionally passing the multiple beams through an imaging system.

19. The cell of claim 18, wherein the multiple beams are reshaped by the diffractive optic, the microlens array, or the imaging system.

20. The cell of claim 16, further comprising a grid of selective emitter regions and current collection fingers disposed with respect to the front surface.

21. The cell of claim 16, wherein the highly doped regions are formed by laser firing a doping ink from on top of and through the front passivation layer into the doped wafer.

22. A process of manufacturing back-contact photovoltaic cells, the process comprising:
applying a first dopant source to a portion of a back surface of a doped wafer of semiconductor material, the first dopant source having a first conductivity type;
applying a second dopant source to a different portion of the back surface of the doped wafer of semiconductor material, the second dopant source having an opposite conductivity type from the first conductivity type;
diffusing the first dopant source and the second dopant source into the doped wafer to form a plurality of first highly doped regions and a plurality of second highly doped regions;
cleaning the back surface;
laying a passivation layer over the back surface, the plurality of first highly doped regions, and the plurality of second highly doped regions;
applying a network of conductors to a portion of the passivation layer; and
forming contacts between the network of conductors and both the first highly doped regions and the second highly doped regions.

23. The process of claim 22, wherein the step of applying the first dopant source and the step of applying the second dopant source comprise inkjet printing, aerosol jet printing, or jet dispensing.

24. The process of claim 22, wherein the step of diffusing the first dopant source and the second dopant source comprises thermal diffusion.

25. The process of claim 24, wherein the thermal diffusion comprises rapid thermal processing.

26. The process of claim 22, wherein the step of laying the passivation layer comprises plasma enhanced chemical vapor deposition, magnetron sputter deposition, or hot-wire chemical vapor deposition.

27. The process of claim 22, wherein the step of applying the network of conductors comprises forming interdigitated fingers.

28. The process of claim 22, wherein the step of forming contacts comprises laser firing contacts.

29. The process of claim 22, wherein the step of laser firing contacts comprises:
passing a laser beam through a diffractive optic or a microlens array to form multiple beams; and
optionally passing the multiple beams through an imaging system.

30. The process of claim 29, wherein the multiple beams are reshaped by the diffractive optic, the microlens array, or the imaging system.

31. The process of claim 22, further comprising:
applying a dilute dopant source of an opposite conductivity type to the doped wafer on the back surface between the plurality of the first highly doped regions and the plurality of the second highly doped regions; and
diffusing the dilute dopant source into the doped wafer to form a shallow emitter.

32. The process of claim 31, further comprising applying an isolation layer or assuring an isolation gap between the shallow emitter and highly doped regions of opposite conductivity type from the shallow emitter.

33. The process of claim 22, wherein the step of laying the passivation layer comprises forming a layer of amorphous silicon and forming a layer of silicon nitride.

34. The process of claim 22, further comprising forming an inversion layer just beneath the back surface and the passivation layer.

35. The process of claim 22, wherein the step of forming an inversion layer comprises:
depositing an undoped layer of an amorphous silicon alloy on the back surface; and
depositing a highly doped layer having a conductivity type opposite the doped wafer on the undoped layer.

36. A process of manufacturing photovoltaic cells, the process comprising:
applying a dopant source to a portion of a front surface of a doped wafer of semiconductor material, the dopant source having a conductivity type opposite the doped wafer;
applying a dilute dopant source having a conductivity type opposite the doped wafer to the remainder of the front surface of the doped wafer;
applying a dopant source to a portion of a back surface of a doped wafer; the dopant source having the same conductivity type as the doped wafer;
diffusing the dopant sources and the dilute dopant source into the doped wafer to form highly doped regions, a shallow emitter, and a back surface field region;
laying a passivation layer over the highly doped regions, the shallow emitter, the back surface and the back surface field region to form a front passivation layer and a back passivation layer;
applying a current collection grid on the front passivation layer;
applying a conductor on the back passivation layer;
forming front-contacts between the highly doped regions and the current collection grid; and
forming back-contacts between the back surface field region and the conductor.

37. The process of claim 36, wherein the steps of forming the front-contacts or forming the back-contacts comprise laser firing contacts.

38. The process of claim 37, wherein the steps of forming the front-contacts or forming the back-contacts comprise parallel laser firing contacts.

39. The process of claim 36, further comprising the step of forming a grid of selective emitter regions and current collection fingers disposed with respect to the front surface.

40. The process of claim 36, wherein:
the step of applying a dopant source to a portion of a front surface of the doped wafer comprises applying a doping ink over the front passivation layer; and
the step of diffusing the dopant sources comprises laser firing the doping ink through the front passivation layer while optionally performing the step of forming front-contacts between the highly doped regions and the current collection grid.
